(19) United States
(12) Patent Application Publication
(10) Pub. No.: US 2025/0316533 A1
(43) Pub. Date: Oct. 9, 2025

(54) CONDUCTIVE PATH WITH REDUCED RESISTANCE

(71) Applicant: Taiwan Semiconductor Manufacturing Company, Ltd., Hsinchu (TW)

(72) Inventors: Te-Chih Hsiung, Taipei (TW); Meng-Chun Chang, Taipei (TW); Han Han, Hsinchu (TW); Ching-Feng Fu, Taichung (TW); Chih-Yuan Ting, Taipei (TW); Chao-Cheng Chen, Hsinchu (TW)

(73) Assignee: Taiwan Semiconductor Manufacturing Company, Ltd., Hsinchu (TW)

(21) Appl. No.: 18/627,885

(22) Filed: Apr. 5, 2024

(51) Int. Cl. H01L 21/768; H01L 21/8238; H01L 27/092; H01L 29/06; H01L 29/417; H01L 29/423; H01L 29/66; H01L 29/775; H01L 29/78; H01L 29/786

(52) U.S. Cl. CPC H01L 21/76832; H10D 30/014; H10D 30/024; H10D 30/43; H10D 30/6211; H10D 30/6219; H10D 30/6729; H10D 30/6735; H10D 30/6757; H10D 62/121; H10D 64/017; H10D 84/0193; H10D 84/038; H10D 84/853

(57) ABSTRACT

Provided are semiconductor devices with reduced resistance in conductive paths from gates to contacts and methods for fabricating such devices. An exemplary method includes forming an epitaxial feature adjacent to a gate, wherein the gate lies over an uppermost surface of a semiconductor fin at a first vertical height; forming a first dielectric material over the epitaxial feature; forming a capping layer over the first dielectric material; forming a second dielectric material over the capping layer; forming an opening over the epitaxial feature, wherein the opening has a sidewall; and forming a side layer over the sidewall of the opening, wherein the side layer extends to a lowest edge at a second vertical height at or above the first vertical height.

### BACKGROUND

The electronics industry has experienced an ever-increasing demand for smaller and faster electronic devices which are simultaneously able to support a greater number of increasingly complex and sophisticated functions. Accordingly, there is a continuing trend in the semiconductor industry to manufacture low-cost, high-performance, and low-power integrated circuits (ICs). Thus far the demand has been met in large part by scaling down semiconductor IC dimensions (e.g., minimum feature size) and thereby improving production efficiency and lowering associated costs. However, such scaling has also introduced increased complexity to the semiconductor manufacturing process. Thus, the realization of continued advances in semiconductor ICs and devices calls for similar advances in semiconductor manufacturing processes and technology.

Multi-gate devices have been introduced in an effort to improve gate control by increasing gate-channel coupling, reduce OFF-state current, and reduce short-channel effects (SCEs). One such multi-gate device that has been introduced is the fin field-effect transistor (FinFET). The FinFET gets its name from the fin-like structure which extends from a substrate on which it is formed, and which is used to form the FET channel. Another multi-gate device, introduced in part to address performance challenges associated with FinFETs, is the gate-all-around (GAA) transistor. GAA devices get their name from the gate structure which extends completely around the channel, providing better electrostatic control than FinFETs. FinFET devices and GAA devices are compatible with conventional complementary metal-oxide-semiconductor (CMOS) processes. Further, the three-dimensional structure of such devices allows them to be aggressively scaled while maintaining gate control and mitigating SCEs.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a plan view of a layout of a multi-gate device, in accordance with some embodiments.

FIG. 2 is a flow chart illustrating a method, in accordance with some embodiments.

FIGS. 3-26 are perspective or cross-sectional views of the semiconductor device during successive stages of fabrication according to the method of FIG. 2, in accordance with some embodiments.

FIG. 27 is a transmission electron microscope (TEM) image of a semiconductor device, in accordance with some embodiments.

### DETAILED DESCRIPTION

The following disclosure provides many different embodiments, or examples, for implementing different features of the subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “over”, “overlying”, “above”, “upper”, “top”, “under”, “underlying”, “beneath”, “below”, “lower”, “bottom”, “side”, and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

In certain embodiments herein, a “material layer” is a layer that includes at least 50 wt. % of the identified material, for example at least 60 wt. % of the identified material, at least 75 wt. % of the identified material, or at least 90 wt. % of the identified material, or substantially 100 wt. % of the identified material; and a layer that is a “material” includes at least 50 wt. % of the identified material, for example at least 60 wt. % of the identified material, at least 75 wt. % of the identified material, or at least 90 wt. % of the identified material, or substantially 100 wt. % of the identified material. For example, certain embodiments, each of a titanium nitride layer and a layer that is titanium nitride is a layer that is at least 50 wt. %, at least 60 wt. %, at least 75 wt. %, titanium nitride, at least 90 wt. %, or at least 95 wt. %, or substantially 100 wt. %, titanium nitride.

For the sake of brevity, conventional techniques related to conventional semiconductor device fabrication may not be described in detail herein. Moreover, the various tasks and processes described herein may be incorporated into a more comprehensive procedure or process having additional functionality not described in detail herein. In particular, various processes in the fabrication of semiconductor devices are well-known and so, in the interest of brevity, many conventional processes will only be mentioned briefly herein or will be omitted entirely without providing the well-known process details. As will be readily apparent to those skilled in the art upon a complete reading of the disclosure, the structures disclosed herein may be employed with a variety of technologies, and may be incorporated into a variety of semiconductor devices and products. Further, it is noted that semiconductor device structures include a varying number of components and that single components shown in the illustrations may be representative of multiple components.

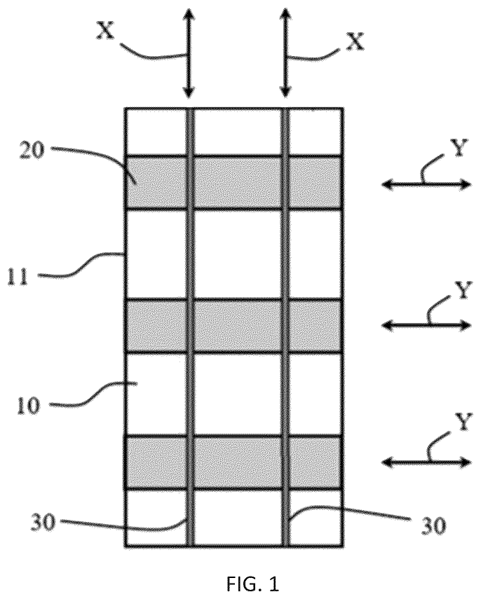

FIG. 1 illustrates a unit cell 11, i.e., a portion of the semiconductor substrate 10 in a semiconductor device 100. As shown, parallel active regions 20 are spaced apart from one another and extend in a Y-direction. Further, parallel gate lines 30 are spaced apart from one another and extend in a X-direction perpendicular to the Y-direction. Exemplary gate lines 30 are formed from conductive material such as metal and form gate structures for the device 100.

The semiconductor device 100 may be a multi-gate device 100. In various embodiments, the multi-gate device 100 may include a FinFET device, a GAA transistor, or other type of multi-gate device. The multi-gate device 100 is formed over a substrate 10.

The multi-gate devices 100 may include a P-type metal-oxide-semiconductor device 100 or an N-type metal-oxide-semiconductor multi-gate device 100. Specific examples may be presented and referred to herein as FinFET devices 100, on account of their fin-like structure. Also presented herein are embodiments of a type of multi-gate transistor referred to as a gate-all-around (GAA) device 100. A GAA device 100 includes any device that has its gate structure, or portion thereof, formed on four sides of a channel region (e.g., surrounding a portion of a channel region). Devices presented herein also include embodiments that have channel regions disposed in nanosheet channel(s), nanowire channel(s), bar-shaped channel(s), and/or other suitable channel configurations. Herein, the terms “nanosheet” or “nanosheet channel” are intended to include nanowire channel and bar-shaped channel configurations.

In some embodiments, the substrate 10 may be a semiconductor substrate such as a silicon substrate. The substrate 10 may include various layers, including conductive or insulating layers formed on a semiconductor substrate. The substrate 10 may include various doping configurations depending on design requirements as is known in the art. The substrate 10 may also include other semiconductors such as germanium, silicon carbide (SiC), silicon germanium (SiGe), or diamond. Alternatively, the substrate 10 may include a compound semiconductor and/or an alloy semiconductor. Further, the substrate 10 may optionally include an epi layer, may be strained for performance enhancement, may include a silicon-on-insulator (SOI) structure, and/or have other suitable enhancement features.

Presented herein are embodiments of devices that may have one or more channel regions (e.g., nanosheets) associated with a gate structure. For example, a stack of vertically spaced nanosheet channels may be provided. However, one of ordinary skill would recognize that the teaching can apply to a single channel (e.g., single nanosheet) or any number of channels. One of ordinary skill may recognize other examples of semiconductor devices that may benefit from aspects of the present disclosure.

In certain embodiments, a conductive interconnect is formed in contact with a source/drain feature. As used herein, “source/drain region(s)” or “source/drain feature(s)” may refer to a source or a drain, individually or collectively dependent upon the context.

Further, a conductive path from source/drain interconnect to a channel region, such as a nanosheet channel or stack of nanosheet channels is provided with reduced resistance. Specifically, methods herein avoid or reduce dielectric obstructions to a direct, shortest, conductive path from the source/drain interconnect to the channel region and, in particular, to the uppermost nanosheet channel.

Sidewalls of the source/drain interconnect may be insulated by a dielectric liner or layer. In order to avoid or reduce dielectric obstructions to the conductive path, embodiments herein provide for limiting the sidewall dielectric liner to a height at or above the uppermost nanosheet channel. As a result, a direct lateral, horizontal, path from the source/drain interconnect to the uppermost nanosheet channel is provided without dielectric obstruction.

In certain embodiments, a source/drain feature is opened by etching through overlying dielectric material to form a cavity. The depth of the etching process is limited by performing a two-step etch process including a first etch that lands above the source/drain feature and a second etch that lands on the source/drain feature. Selectivity of the second etch limits etching into the source/drain feature. For example, in certain embodiments, the second etch may etch silicon nitride at a faster rate than silicon, silicon germanium, silicon phosphorus, or other source/drain feature material. In certain embodiments, the second etch may etch silicon oxide at a faster rate than silicon, silicon germanium, silicon phosphorus, or other source/drain feature material. Because the depth of the etch into the source/drain feature is limited, the sidewall of the cavity does not extend past the height of the uppermost channel region. Therefore, the sidewall liner formed in the cavity does not extend past the height of the uppermost channel region and is not located in the direct conductive path between the uppermost channel region and the interconnect that is formed in and below the cavity.

In certain embodiments, current crowding is prevented by the methods described herein. Thus, device performance is boosted or improved over devices in which dielectric sidewall liners obstruct conductive paths.

In certain embodiments, etching of epitaxial material by the process for forming the conductive interconnect cavity is minimized. Specifically, the higher oxide to silicon or the higher nitride to silicon etch selectivity minimized etching of the epitaxial material.

By minimizing the epitaxial recess amount, the following dielectric deposition process may locate the bottom of the dielectric sidewall layer at a location or height at or above the uppermost nanosheet channel. Preventing location of the dielectric sidewall layer directly between the uppermost nanosheet channel and the conductive interconnect provides for lower resistance and prevents current crowding. A deeper etch into the epitaxial material would induce deposition of the dielectric sidewall layer at a height lower than the uppermost nanosheet, block current flow into the uppermost nanosheet, and cause higher resistance. Embodiments herein avoid formation of such high resistance structures.

Therefore, embodiments herein may locate the bottom edge of the dielectric sidewall liner around the conductive interconnect to a height at or above the uppermost nanosheet. Embodiments herein may provide for current flow into the uppermost nanosheet without current crowding. Embodiments herein may provide for lower resistance of the nanosheet channel. Embodiments herein may utilize a feature opening etch with an etch selectivity providing for a first etch rate of silicon oxide, a second etch rate of silicon nitride, and a third etch rate of epitaxial material, such as silicon, silicon germanium, silicon phosphorus, or the like, wherein the first etch rate is faster or higher than the second etch rate, and the second etch rate is faster or higher than the third etch rate. Thus, the epitaxial recess amount is minimized.

Embodiments of the present disclosure offer advantages over the existing art, though it is understood that other embodiments may offer different advantages, not all advantages are necessarily discussed herein, and no particular advantage is required for all embodiments.

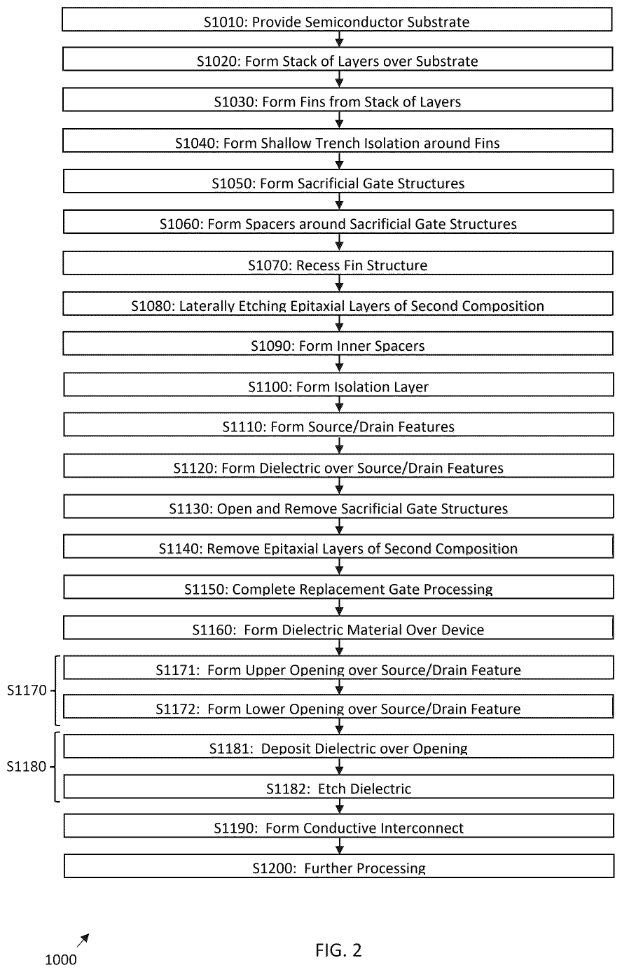

Referring to FIG. 2, illustrated therein is a method 1000 of fabrication of a semiconductor device 200 (such as a multi-gate device 100), in accordance with various embodiments. Method 1000 is discussed below with reference to a GAA device having a channel region that may be referred to as a nanosheet or nanosheet channel and which may include various geometries (e.g., cylindrical, bar-shaped) and dimensions. However, it will be understood that aspects of method 1000 may be equally applied to other types of multi-gate devices without departing from the scope of the present disclosure. In some embodiments, method 1000 may be used to fabricate the multi-gate device 100, described above with reference to FIG. 1. Thus, one or more aspects discussed above with reference to the multi-gate device 100 may also apply to method 1000. It is understood that method 1000 includes steps having features of a complementary metal-oxide-semiconductor (CMOS) technology process flow and thus, are only described briefly herein. Also, additional steps may be performed before, after, and/or during method 1000.

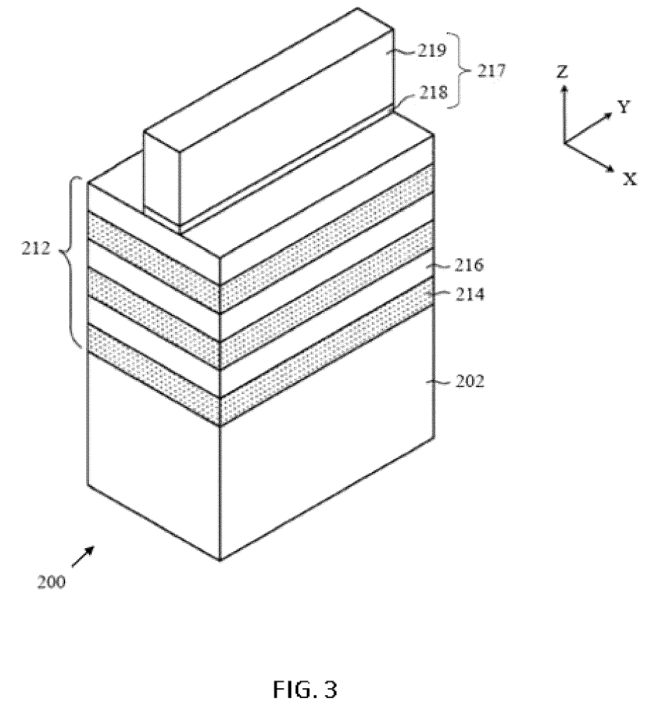

Method 1000 is described below with reference to FIGS. 3-26, which provide perspective views of the multi-gate device 200, cross-sectional views of the multi-gate device 200 along a plane substantially parallel to a plane defined by the X and Z axes in FIG. 1, and cross-sectional views of the multi-gate device 200 along a plane substantially parallel to a plane defined by the Y and Z axes in FIG. 1, as described, illustrating various stages of fabrication according to method 1000.

Further, the semiconductor device 200 may include various other devices and features, such as other types of devices such as additional transistors, bipolar junction transistors, resistors, capacitors, inductors, diodes, fuses, static random-access memory (SRAM) and/or other logic circuits, etc., but is simplified for a better understanding of the concepts of the present disclosure. In some embodiments, the semiconductor device 200includes a plurality of semiconductor devices (e.g., transistors), including PFETs, NFETs, etc., which may be interconnected. Moreover, it is noted that the process steps of method 1000, including any descriptions given with reference to the figures are merely exemplary and are not intended to be limiting beyond what is specifically recited in the claims that follow.

At operation S1010, the method 1000 provides a substrate 202, as shown in FIG. 3. In some embodiments, the substrate 202 may be a semiconductor substrate such as a silicon (Si) substrate. The substrate 202 may include various layers, including conductive or insulating layers formed on a semiconductor substrate. The substrate 202 may include various doping configurations depending on design requirements as is known in the art. For example, different doping profiles (e.g., p-well, n-well) may be formed on the substrate 202 in regions designed for different device types (e.g., n-type field effect transistors (NFET), p-type field effect transistors (PFET)). The suitable doping may include ion implantation of dopants and/or diffusion processes, such as boron (B) for the p-well and phosphorous (P) for the n-well. In some embodiments, the substrate 202 includes a single crystalline semiconductor layer on at least its surface portion. The substrate 202 may comprise a single crystalline semiconductor material such as, but not limited to Si, Ge, SiGe, GaAs, InSb, GaP, GaSb, InAlAs, InGaAs, GaSbP, GaAsSb and InP. Alternatively, the substrate 202 may include a compound semiconductor and/or an alloy semiconductor. In the illustrated embodiment, the substrate 202 is made of crystalline Si.

As shown in FIG. 3, at operation S1020, the method 1000 (FIG. 2) forms one or more epitaxial layers over the substrate 202. In some embodiments, an epitaxial stack 212 is formed over the substrate 202. The epitaxial stack 212 includes epitaxial layers 214 of a first composition interposed by epitaxial layers 216 of a second composition. The first and second composition may be different. Embodiments are possible including those that provide for a first composition and a second composition having different oxidation rates and/or etch selectivity. In an embodiment, the epitaxial layers 214 are SiGe and the epitaxial layers 216 are silicon. In embodiments wherein the epitaxial layer 214 includes SiGe and the epitaxial layer 216 includes silicon, the silicon oxidation rate is less than the SiGe oxidation rate. It is noted that three layers of epitaxial layers 214 and three layers of epitaxial layers 216 are illustrated in FIG. 3, which is for illustrative purposes only and not intended to be limiting beyond what is specifically recited in the claims. It can be appreciated that any number of epitaxial layers may be formed in the epitaxial stack 212; the number of layers depending on the desired number of channels regions for the GAA device 200. In some embodiments, the number of epitaxial layers 216 is between two and ten, such as six or seven.

In some embodiments, the epitaxial layer 214 has a thickness ranging from about five nanometers to about fifteen nanometers. The epitaxial layers 214 may be substantially uniform in thickness. In some embodiments, the epitaxial layer 216 has a thickness ranging from about five nanometers to about fifteen nanometers. In some embodiments, the epitaxial layers 216 of the stack are substantially uniform in thickness. As described in more detail below, the epitaxial layer 216 may serve as channel region(s) for a subsequently formed multi-gate device and has a thickness chosen based on device performance considerations. The epitaxial layer 214 may serve to define a gap between adjacent channel region(s) for a subsequently formed multi-gate device and has a thickness chosen based on device performance considerations.

By way of example, epitaxial growth of the epitaxial stack 212 may be performed by a molecular beam epitaxy (MBE) process, a metalorganic chemical vapor deposition (MOCVD) process, and/or other suitable epitaxial growth processes. In some embodiments, the epitaxially grown layers such as, the epitaxial layers 216 include the same material as the substrate 202. In some embodiments, the epitaxially grown layers 214 and 216 include a different material than the substrate 202. As stated above, in at least some examples, the epitaxial layer 214 includes an epitaxially grown Si₁₋ₓGeₓ layer (wherein x is from about 10 to about 55%) and the epitaxial layer 216 includes an epitaxially grown silicon (Si) layer. Alternatively, in some embodiments, either of the epitaxial layers 214 and 216 may include other materials such as germanium, a compound semiconductor such as silicon carbide, gallium arsenide, gallium phosphide, indium phosphide, indium arsenide, and/or indium antimonide, an alloy semiconductor such as SiGe, GaAsP, AlInAs, AlGaAs, InGaAs, GalnP, and/or GaInAsP, or combinations thereof. As discussed, the materials of the epitaxial layers 214 and 216 may be chosen based on providing differing oxidation, etch selectivity properties. In various embodiments, the epitaxial layers 214 and 216 are substantially dopant-free (i.e., having an extrinsic dopant concentration from about 0 cm⁻³ to about 1×10¹⁷ cm⁻³), where for example, no intentional doping is performed during the epitaxial growth process. In some embodiments, the bottom layer and the top layer of the epitaxial stack 212 are SiGe layers (not shown). In alternative embodiments, the bottom layer of the epitaxial stack 212 is a Si layer and the top layer of the epitaxial stack 212 is a SiGe layer (not shown).

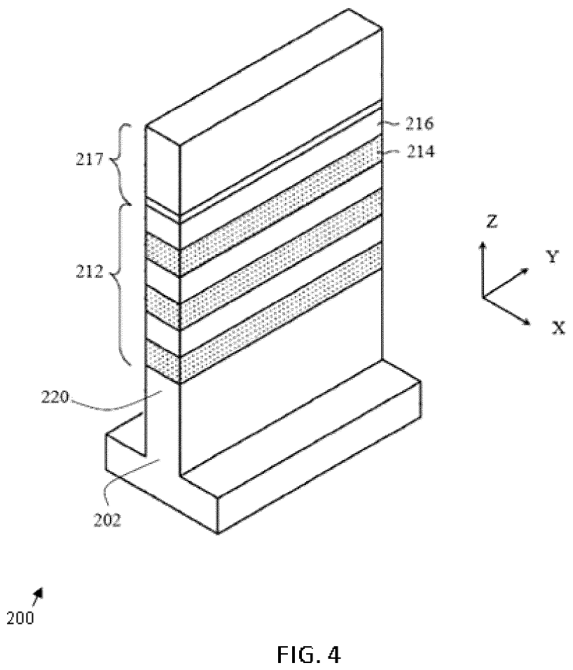

As shown in FIGS. 3-4, at operation S1030, the method 1000 (FIG. 2) patterns the epitaxial stack 212 to form a semiconductor fin 220. In some embodiments, the operation S1030 includes forming a mask layer 217 over the epitaxial stack 212, as shown in FIG. 3. The mask layer 217 includes a first mask layer 218 and a second mask layer 219. An exemplary first mask layer 218 is a pad oxide layer made of a silicon oxide, which may be formed by a thermal oxidation. An exemplary second mask layer 219 is made of a silicon nitride (SiN), which may be formed by chemical vapor deposition (CVD), including low pressure CVD (LPCVD) and plasma enhanced CVD (PECVD), physical vapor deposition (PVD), atomic layer deposition (ALD), or other suitable process. The mask layer 217 is patterned into a mask pattern by using patterning operations including photolithography and etching. Operation S1030 subsequently patterns the epitaxial stack 212 in an etching process, such as a dry etch (e.g., reactive ion etching), a wet etch, and/or other suitable process, through openings defined in the patterned mask layer 217. The stacked epitaxial layers 214 and 216 are thereby patterned into the fin 220. While FIG. 4 illustrates the formation of one fin 220, any suitable number of the fins may be formed. Trenches are etched between adjacent fins 220.

In various embodiments, each fin 220 includes an upper portion of the interleaved epitaxial layers 214 and 216, and a bottom portion that is formed from the etched substrate 202. Each fin 220 protrudes upwardly in the Z-direction from the substrate 202 and extends lengthwise in the Y-direction. Sidewalls of each fin 220 may be straight or inclined (not shown). In FIG. 4, additional fins would be spaced apart along the X-direction. The fins 220 may have a same width or different widths.

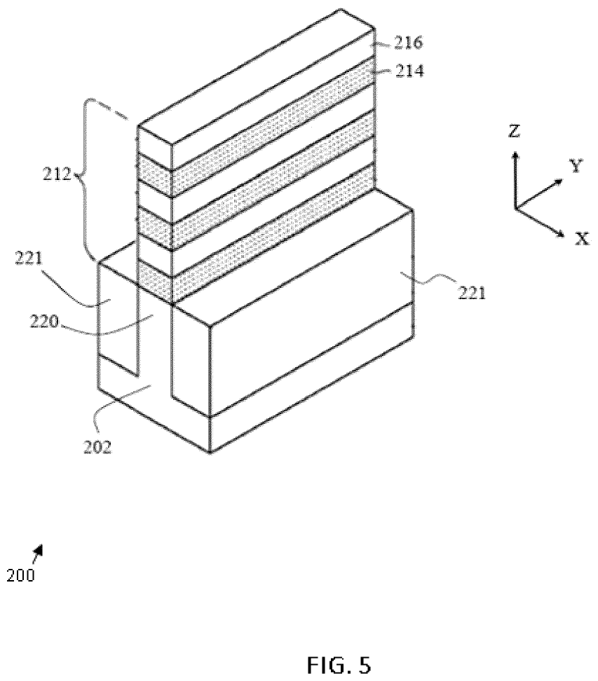

As shown in FIG. 5, at operation S1040, the method 1000 (FIG. 2) forms shallow trench isolation (STI) features (also denoted as STI features) 221 in trenches adjacent to each fin 220 with a dielectric layer. The STI features 221 may be formed by first filling the trenches around each fin 220 with a dielectric material layer to cover top surfaces and sidewalls of the fin 220 (not shown). The dielectric material layer may include one or more dielectric materials. Suitable dielectric materials for the dielectric layer may include silicon oxides, silicon nitrides, silicon carbides, fluorosilicate glass (FSG), low-K dielectric materials, and/or other suitable dielectric materials. The dielectric material may be deposited by any suitable technique including thermal growth, flowable CVD (FCVD), HDP-CVD, PVD, ALD, and/or spin-on techniques. The dielectric material layer is then planarized by using, for example, chemical mechanical planarization (CMP), until top surfaces of the mask layer 217 are revealed, and the dielectric material layer is recessed to form the shallow trench isolation (STI) features (also denoted as STI features) 221, as shown in FIG. 5. In the illustrated embodiment, the STI features 221 are formed on the substrate 202. Any suitable etching technique may be used to recess the isolation features 221 including dry etching, wet etching, RIE, and/or other etching methods, and in an exemplary embodiment, an anisotropic dry etching is used to selectively remove the dielectric material of the isolation features 221 without etching the fin 220. The mask layer 217 (shown in FIG. 4) may also be removed before, during, and/or after the recessing of the isolation features 221. In some embodiments, the mask layer 217 is removed by the CMP process performed prior to the recessing of the isolation features 221. In some embodiments, the mask layer 217 is removed by an etchant used to recess the isolation features 221.

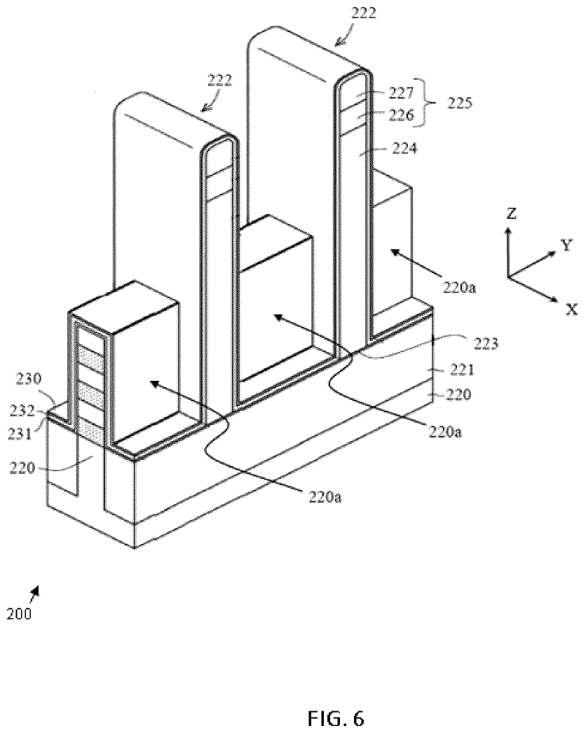

As shown in FIG. 6, at operation S1050, the method 1000 (FIG. 2) forms sacrificial (dummy) gate structures 222. The sacrificial gate structures 222 are formed over portions of the fin 220 which are to be channel regions. The sacrificial gate structures 222 may extend over a number of adjacent fins (not shown). The sacrificial gate structures 222 lie directly over and define the channel regions of the GAA devices to be formed. Each of the sacrificial gate structures 222 includes a sacrificial gate dielectric 223 and a sacrificial gate electrode 224 over the sacrificial gate dielectric 223. As shown, the gate structures 222 extend lengthwise in the X-direction and are spaced apart in the Y-direction.

The sacrificial gate structures 222 are formed by first blanket depositing a sacrificial gate dielectric layer over the fin(s) 220. A sacrificial gate electrode layer is then blanket deposited on the sacrificial gate dielectric layer and over the fin(s) 220. The sacrificial gate dielectric layer includes silicon oxide, silicon nitride, or a combination thereof. The thickness of the sacrificial gate electrode layer is in a range from about one hundred nanometers to about two hundred nanometers in some embodiments. The sacrificial gate electrode layer 224 includes silicon such as polycrystalline silicon or amorphous silicon. The thickness of the sacrificial gate dielectric layer is in a range from about one nanometer to about five nanometers in some embodiments. In some embodiments, the sacrificial gate electrode layer is subjected to a planarization operation. The sacrificial gate dielectric layer and the sacrificial gate electrode layer are deposited using CVD, including LPCVD and PECVD, PVD, ALD, or other suitable process. A mask layer 225 is formed over the sacrificial gate electrode layer. The mask layer 225 may include a mask layer 226 such as silicon oxide and a mask layer 227 such as silicon nitride. Subsequently, a patterning operation is performed on the mask layer 225, the sacrificial gate electrode layers and the sacrificial gate dielectric layer are patterned into the sacrificial gate structures 222, including sacrificial gate dielectric layer 223 and sacrificial gate electrode 224.

As shown, the fin 220 is partially exposed between and on opposite sides of the sacrificial gate structures 222, thereby defining source/drain (S/D) regions. In this disclosure, a source and a drain are interchangeably used and the structures thereof are substantially the same.

Still referring to FIG. 6, at operation S1060, the method 1000 (FIG. 2) forms spacers 230 on sidewalls of the sacrificial gate structures 222 and sidewalls of the fins 220 by depositing spacer materials, followed by an etching. The spacers 230 may include spacer material such as silicon oxide, silicon nitride, silicon carbide, silicon oxynitride, SiCN films, silicon oxycarbide, SiOCN films, and/or combinations thereof. In some embodiments, each of the spacers 230 include multiple layers, such as a liner layer 231 and a main spacer layer 232 on a sidewall of the liner layer 231.

By way of example, the spacers 230 may be formed by depositing spacer material including a liner material layer and a dielectric material layer over the sacrificial gate structure 222 using processes such as a subatmospheric CVD (SACVD) process, a flowable CVD process, an ALD process, a PVD process, or other suitable process respectively.

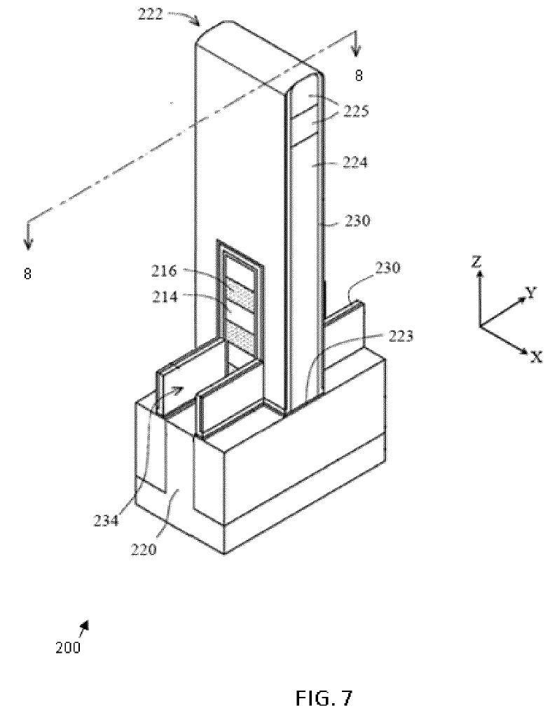

As shown in FIG. 7, the deposition of the liner material layer and the dielectric material layer are followed by, at operation S1070, etching-back (e.g., anisotropically) to expose, and remove, portions 220a of the fins 220 adjacent to and not covered by the sacrificial gate structure 222 (e.g., S/D regions). The liner material layer and the dielectric material layer may remain on the sidewalls of the sacrificial gate structure 222 as the gate sidewall spacers 230, and on the sidewalls of the fins as the fin sidewall spacers 230. In some embodiments, the etching-back process may include a wet etch process, a dry etch process, a multiple-step etch process, and/or a combination thereof. The spacers 230 may have a thickness ranging from about five nanometers to about twenty nanometers.

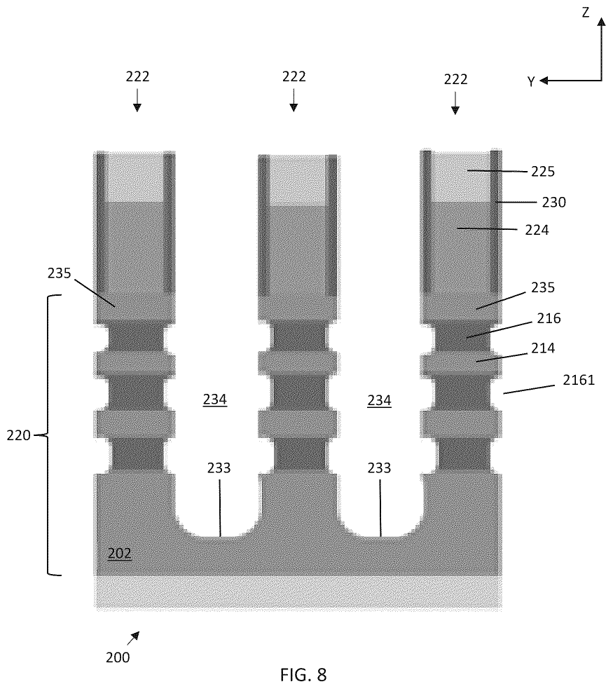

Cross-referencing FIG. 7 with FIG. 8, a cross-sectional view taken along line 8-8 in FIG. 7, i.e., an X-cut cross-sectional view, at operation S1070, the method 1000 (FIG. 2) recesses the portions of the fin 220 not covered by the sacrificial gate structures 222 to form gaps or recesses 234 in the S/D regions. It is noted that FIG. 7 shows only one sacrificial gate structure 222 and the adjacent portion of fin 220 so that etching of the S/D region between the sacrificial gate structures 222 of FIG. 6 may be more clearly viewed. FIG. 8 is a cross sectional-view along line 8-8 in FIG. 7 but illustrates three sacrificial gate structures 222 and a fin 220 lying under the sacrificial gate structures 222.

As shown most clearly in FIG. 8, the stacked epitaxial layers 214 and 216 are etched to a bottom gap surface 233 formed by the fin 220. In many embodiments, the operation S1070 forms the gaps 234 by a suitable etching process, such as a dry etching process, a wet etching process, or a combination thereof. As a result of the etching process, fin segments 235 of the upper portion of the fin 220 are defined and separated from one another by the gaps 234.

As further shown in FIG. 8, method 1000 (FIG. 2) includes laterally etching the epitaxial layers 216 of the second composition at operation S1080. In an exemplary embodiment, an SiGe etchback process is removed to laterally recess the layers 216. As a result, pockets 2161 are formed laterally adjacent to the layers 216 and vertically adjacent to the layers 214.

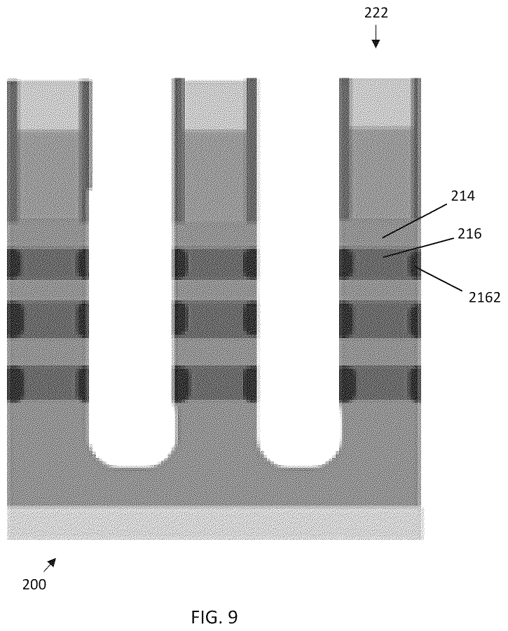

As shown in FIG. 9, method 1000 (FIG. 2) includes forming inner spacers 2162 in the pockets 2161 laterally adjacent to epitaxial layers 216 at operation S1090. FIG. 9 is an X-cut cross-sectional view. In exemplary embodiments, the inner spacers 2162 may be formed from silicon oxides, silicon nitrides, silicon carbides, silicon carbide nitride, silicon oxide carbide, silicon carbide oxynitride, and/or other suitable dielectric materials. The inner spacers 2162 may be formed by ALD or any other suitable method. As shown, after deposited the material forming inner spacers 2162, the material may be trimmed from the sidewalls of epitaxial layers 214.

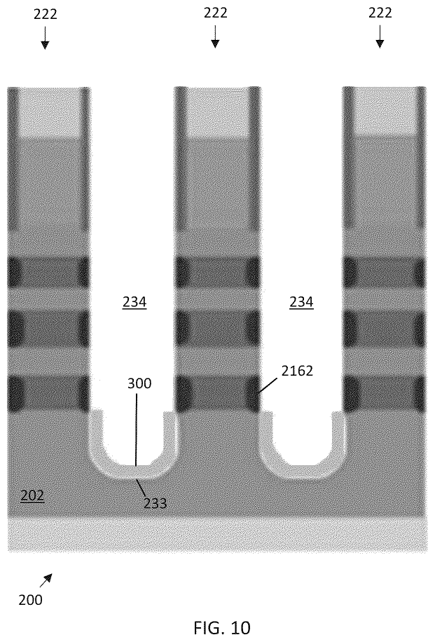

Referring to FIG. 10, method 1000 (FIG. 2) continues, at operation S1100, with forming an isolation layer 300 over the semiconductor substrate 202. Specifically, the isolation layer 300 is formed on the bottom surfaces 233 of the gaps 234. In exemplary embodiments, the isolation layer 300 is formed by an atomic layer deposition (ALD) process.

FIG. 10 is an X-cut cross-sectional view. As shown, the isolation layer 300 may completely cover the bottom gap surface 233 such that no portion of the semiconductor substrate 202 between the bottom inner spacers 2162 is uncovered. Thus, each portion of the isolation layer 300 extends from one gate structure 222 to an adjacent gate structure 222.

In exemplary embodiments, the isolation layer 300 is a dielectric material with a large band gap. For example, the isolation layer 300 may be formed from a material with a band gap of at least 4 eV, such as at least 4.5 eV, at least 5 eV, at least 5.5 eV, at least 6 eV, at least 6.5 eV, at least 7 eV, at least 7.5 eV, at least 8 eV, at least 8.5 eV, or at least 8.9 eV.

In certain embodiments, the isolation layer 300 is formed from silicon nitride (SiN) and has a band gap of about 5 eV. In certain embodiments, the isolation layer 300 is formed from silicon oxide (SiO) and has a band gap of about 8.9 eV. In exemplary embodiments, the isolation layer 300 is formed from silicon oxide, silicon nitride, or a combination thereof.

In exemplary embodiments, the isolation layer includes a plurality of sublayers, such that the isolation layer is a multi-film structure. Such sublayers may be separately deposited. The thickness and order of sublayers within the multi-film structure may be designed to provide a desired band gap, a desired dielectrics constant, and to facilitate epitaxial growth of material for forming source/drain regions over the isolation layer as described below.

In exemplary embodiments, the isolation layer 300 has a small dielectrics constant (or relative permittivity). In exemplary embodiments, the isolation layer has a dielectric constant of less than ten, such as less than 7.5, less than five, or less than four.

While FIGS. 9-10 describe an isolation layer 300 that is formed after forming the inner spacers 2162, it is contemplated that such layer be formed simultaneously with the inner spacers 2162.

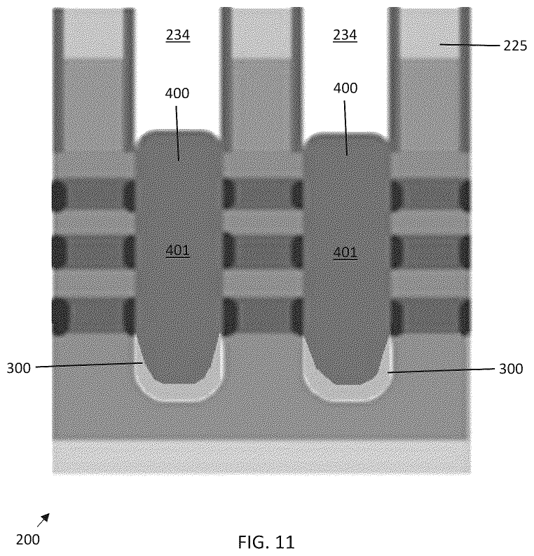

The method may continue, at operation S1110, with forming source/drain features 400, as shown in FIG. 11. FIG. 11 is an X-cut cross-sectional view. In exemplary embodiments, the source/drain features 400 are formed by epitaxial growth. For example, operation S1110 may include selectively growing epitaxial material over the isolation layer 300 to form source/drain features 400. In exemplary embodiments, the source/drain features 400 are strained source/drain features 400.

The epitaxial material may include one or more layers of Si, SiP, SiC and SiCP for an n-channel FET or Si, SiGe, Ge for a p-channel FET. For the P-channel FET, boron (B) may also be contained in the source/drain. The source/drain epitaxial layers may be formed by an epitaxial growth method using CVD, ALD, or molecular beam epitaxy (MBE).

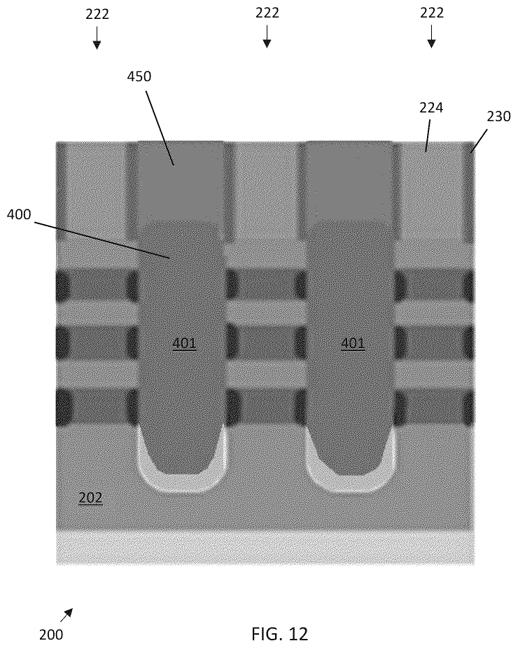

In FIG. 12, method 1000 includes, at operation S1120, forming dielectric 450 over the source/drain features 400. Specifically, the gaps 234 are filled with dielectric 450. In exemplary embodiments, the dielectric 450 is a first interlayer dielectric layer (ILD). The dielectric 450 may be silicon oxide or other suitable dielectric material.

FIG. 12 is an X-cut cross-sectional view. While not shown in FIG. 12, a liner may be formed over the source/drain features 400 before the dielectric 450 is deposited. In certain embodiments, the liner may be silicon nitride or another suitable material.

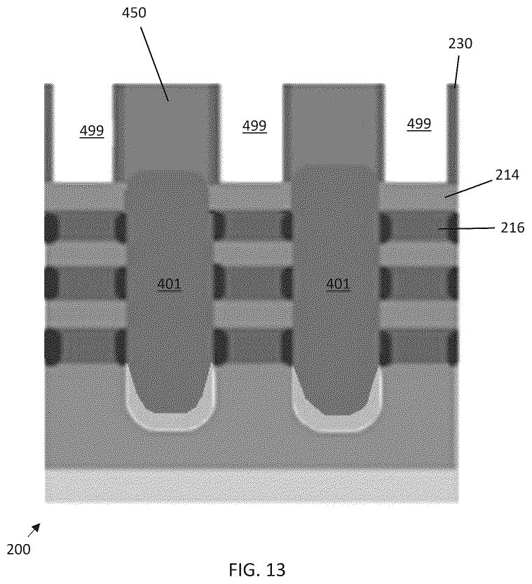

As further shown in FIG. 13, method 1000 includes, at operation S1130, opening and removing the sacrificial gate structures 222. Specifically, a chemical mechanical planarization (CMP) process may be performed to remove the mask layer 225 and to uncover the sacrificial gate electrode 224. Further, the sacrificial gate electrode 224 is removed to form gate cavities 499. As shown, the gate cavities 499 are bounded by the spacers 230 and by the uppermost epitaxial layer 214. FIG. 13 is an X-cut cross-sectional view.

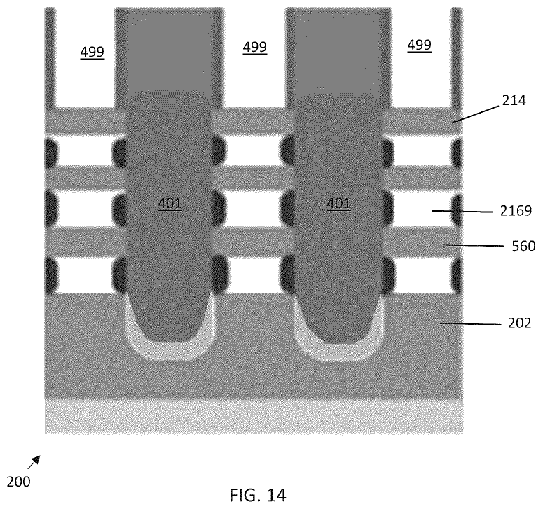

In FIG. 14, method 1000 removes the epitaxial layers 216 of the second composition at operation S1140. As a result, gaps 2169 are formed between the epitaxial layers 214 of the first composition. In this manner, the epitaxial layers 214 of the first composition are formed as vertically-spaced apart semiconductor nanosheets 560. FIG. 14 is an X-cut cross-sectional view.

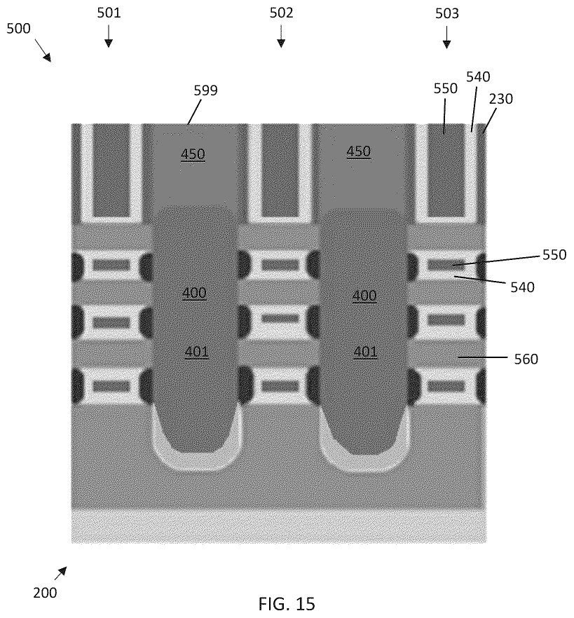

In FIG. 15, method 1000 includes, at operation S1150, completing a replacement metal gate process to form gate structures 500, such as gate structure 501, gate structure 502, and gate structure 503. FIG. 15 is an X-cut cross-sectional view.

In exemplary embodiments, the replacement metal gate process includes forming a gate dielectric layer 540 in the gate cavities 499 and in the gaps 2169, and forming a gate electrode material 550 over the gate dielectric layer 540 to fill the gate cavities 499 and fill the gaps 2169.

An exemplary gate dielectric layer(s) 540 is deposited conformally in the gate cavities 499 and gaps 2169. The gate dielectric 540 may be formed on the semiconductor nanosheets 560, and the gate electrode material 550 may be formed on the gate dielectric layer(s) 540. Thus, each semiconductor nanosheet 560 is wrapped in gate dielectric 540 and surrounded by gate electrode material 550.

In accordance with some embodiments, the gate dielectric layer(s) 540 comprises silicon oxide, silicon nitride, or multilayers thereof. In some embodiments, the gate dielectric layer(s) 540 is a high-k dielectric material, and in these embodiments, the gate dielectric layer(s) 540 may have a k value greater than about 7.0, and may include a metal oxide or a silicate of Hf, Al, Zr, La, Mg, Ba, Ti, Pb, and combinations thereof. The formation methods of the gate dielectric layer(s) 540 may include Molecular-Beam Deposition (MBD), ALD, PECVD, and the like.

The gate electrode material 550 is deposited over the gate dielectric layer(s) 540 and fills the remaining portion of the gate cavity. The gate electrode material 550 may be a metal-containing material such as TiN, TaN, TaC, Co, Ru, Al, combinations thereof, or multi-layers thereof. For example, although a single gate electrode material is illustrated, any number of work function tuning layers may be deposited.

As shown, the FIG. 15, the replacement metal gate process further includes removing excess portions of the gate dielectric layer(s) 540 and the gate electrode material 550 located over the top surface of the ILD 450. For example, a planarization process, such as a CMP process, may be performed to remove the excess portions of the gate dielectric layer(s) 540 and the gate electrode material 550. As a result, the device 200 has an upper surface 599. The remaining portions of material of the gate dielectric layer(s) 540 and the gate electrode material 550 thus form the replacement gate structure 500 of the resulting device 200. The gate dielectric layer(s) 540 and gate electrode material 550 may be collectively referred to as a “gate,” a “gate stack,” or a “gate structure.” Each gate structure 500 may extend along sidewalls of a channel region of the fin structures.

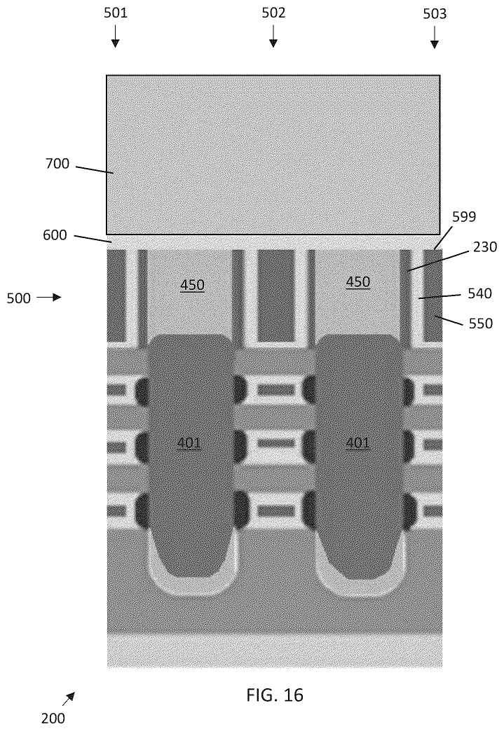

In FIG. 16, the method may include forming dielectric material over the device 200 at operation S1160. For example, a layer 600, such as a contact etch stop layer (CESL) or capping layer, may be formed over the surface 599. In exemplary embodiments, the layer 600 has a vertical thickness, in the Z-direction, of from one to five nanometers. FIG. 16 is an X-cut cross-sectional view.

Operation S1160 further includes forming a second interlayer dielectric (ILD) layer 700 over layer 600. In certain embodiments, the second interlayer dielectric (ILD) layer 700 is silicon oxide or another suitable material. In certain embodiments, the second ILD layer 700 and the first ILD layer 450 are the same material, for example silicon oxide.

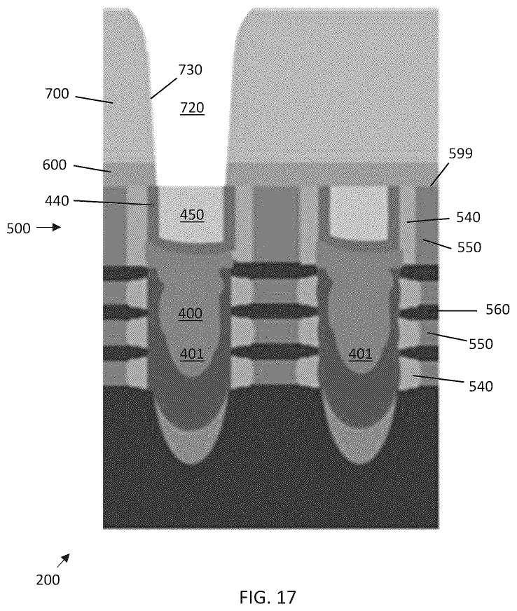

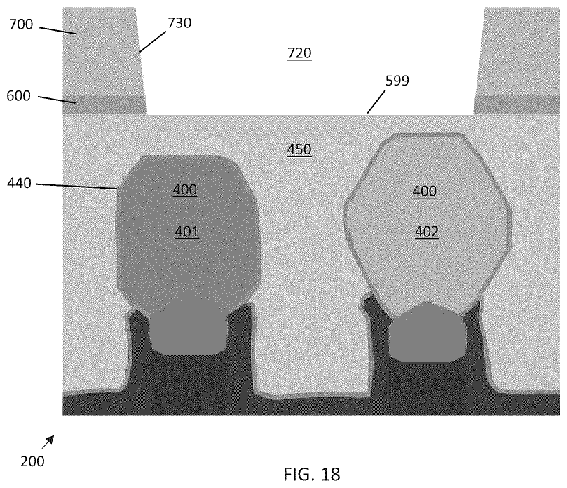

At FIGS. 17 and 18, method 1000 includes, at operation S1171, performing a first etch process to form an upper opening 720 over a selected source/drain feature 400. FIG. 17 is an X-cut cross-sectional view, and FIG. 18 is a Y-cut cross-sectional view of the stage of fabrication of FIG. 17, along across two source/drain features 400. As shown, the upper opening 720 is defined by sidewalls 730 formed by the ILD layer 700 and the layer 600.

It is noted that in FIGS. 17 and 18, a dielectric liner 440 is located under and around the dielectric 450, i.e., between the dielectric 450 and the source/drain feature 400 and between the dielectric 450 and the gate dielectric 540. In certain embodiments, the dielectric liner 440 and the layer 600 are the same material, for example silicon nitride.

In an exemplary embodiment, the first etch process has an etch selectivity such that the layer 600 is removed at a faster or higher etch rate than the dielectric material 450. In an exemplary embodiment, the first etch process has an etch selectivity such that the layer 600 is removed at a faster or higher etch rate than the dielectric material 700. With the selected etch selectivity, the first etch process may be performed to land on the upper surface 599 of the dielectric 450 as shown.

As shown in FIG. 18, in exemplary embodiments, the source/drain features 400 may include an n-type epitaxial material source/drain feature 401 and a p-type epitaxial material source/drain feature 402.

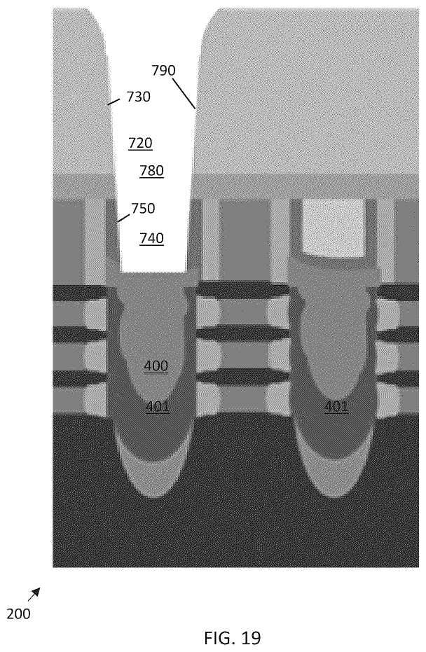

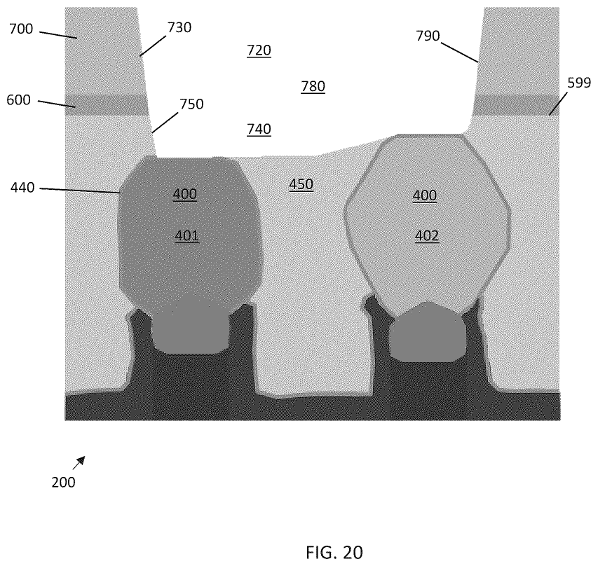

At FIGS. 19 and 20, method 1000 includes, at operation S1172, performing a second etch process to form a lower opening 740 over a selected source/drain feature 400. FIG. 19 is an X-cut cross-sectional view, and FIG. 20 is a Y-cut cross-sectional view of the stage of fabrication of FIG. 17, across two source/drain features 400.

As shown, the second etch process etches the dielectric 450 to form a lower opening 740 defined by sidewalls 750. The upper opening 720 and lower opening 740 collectively define an opening 780 over the selected source/drain feature 400. Likewise, the lower sidewalls 750 and upper sidewalls 730 collected define opening sidewalls 790.

The second etch process may land on the source/drain features 400 and/or on the liner 440 around the source/drain features 400.

In an exemplary embodiment, the second etch process has an etch selectivity such that the dielectric 450 and/or the liner 440 are removed at a faster or higher etch rate than the material of the source/drain features 400. With the selected etch selectivity, the second etch process may be performed to land on the liner 440 and/or the dielectric 450 while minimizing removal of material from the source/drain features 400.

Collectively, the first etch process of operation S1171 and the second etch process of operation S1172 represent an operation S1170 of forming an opening 780 over the selected source/drain feature 400. As described, the first etch process is selective to removing the layer 600 relative to the dielectric 450 and lands on the dielectric 450. Further, the second etch process is selective to removing the dielectric 450 or the liner 440 relative to the source/drain or epitaxial feature 400.

In certain embodiments, the first etch process is performed at a first temperature with a first power, the second etch process is performed at a second temperature with a second power, the first temperature is lower than the second temperature, and the first power is greater than the second power.

For example, in certain embodiments the first etch process is a soft landing etch process. In certain embodiments, the first etch process is a plasma etch process performed with gas mixtures including C₄F₈, C₄F₆, O₂, Ar, He, N₂, and/or other suitable gases. In certain embodiments, the first etch process is a plasma etch process performed at a first pressure of from three to one hundred millitorr (mT). In certain embodiments, the first etch process is a plasma etch process performed with a first power of from zero to five hundred watts (W). In certain embodiments, the first etch process is a plasma etch process performed with a first plasma frequency of from 0.8 megahertz (MHz) to sixty (60) MHz.

In certain embodiments, the second etch process is a high temperature plasma etch. For example, in certain embodiments, the wafer temperature during the second etch process is from eighty to two hundred degrees Celsius. In certain embodiments, the second etch process is a plasma etch process performed with gas mixtures including C₄F₈, C₄F₆, O₂, Ar, He, N₂, and/or other suitable gases. In certain embodiments, the second etch process is a plasma etch process performed at a second pressure of from three to one hundred millitorr (mT). In certain embodiments, the second etch process is a plasma etch process performed with a second power of from zero to five hundred watts (W). In certain embodiments, the second etch process is a plasma etch process performed with a second plasma frequency of from 0.8 MHz to sixty (60) MHz.

In certain embodiments, the second power is greater than the first power. For example, the second power may be from twenty (20) to one hundred fifty (150) watts greater than the first power.

In certain embodiments, the second plasma frequency is lower than the first plasma frequency, such as for a higher aspect ratio etch. For example, the first plasma frequency may be from twenty seven (27) to forty (40) MHz, and the second plasma frequency may be from two (2) to forty (40) MHz.

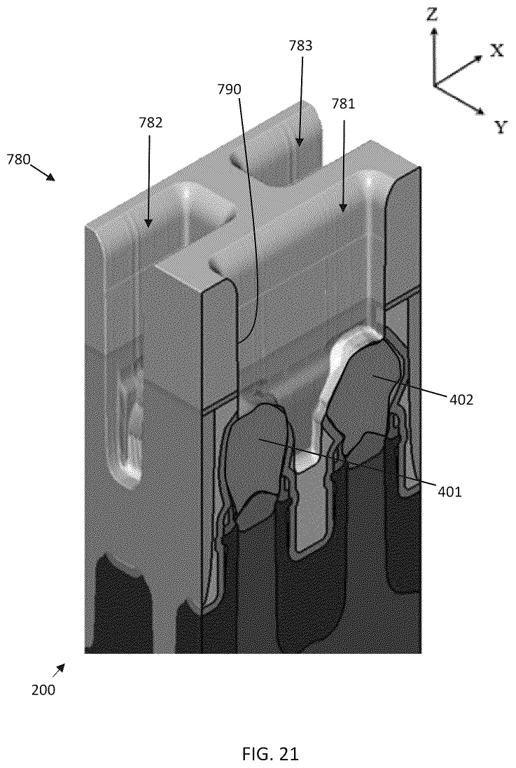

FIG. 21 is a perspective view of the device 200 at the stage of fabrication of FIGS. 19-20. As shown, several openings 780 are formed over the device 200, including a first opening 781, similar to the opening 780, lying over an n-type epitaxial material source/drain feature 401 and a p-type epitaxial material source/drain feature 402.

In FIG. 21, the opening 780 is illustrated as extending deeper, to a depth between the two source/drain features 401 and 402. Yet, the opening sidewall 790 still extends down to, and terminates at, the source/drain features 401 and 402 as shown. Opening 782 and 783 may be separated from the opening 781 in the Y-direction and separated from one another in the X-direction.

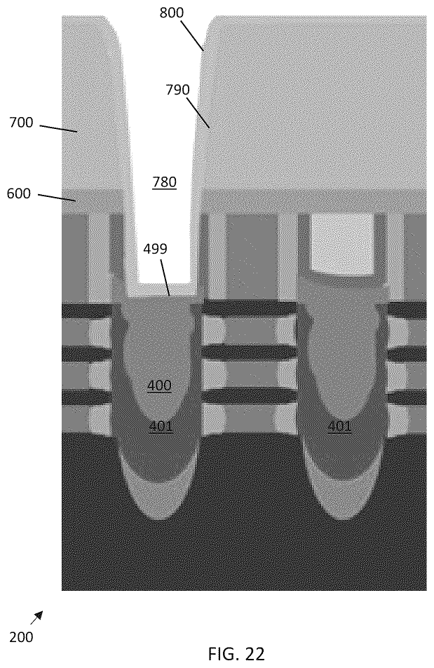

At FIG. 22, method 1000 includes, at operation S1181, depositing a dielectric material 800 over the device 200. Specifically, the dielectric material 800 may be conformally deposited over the opening 780, including on the sidewalls 790 of the opening 780 and over the exposed surface 499 of the selected source/drain feature 400. In certain embodiments, the dielectric material is silicon nitride or another suitable dielectric material. FIG. 22 is an X-cut cross-sectional view.

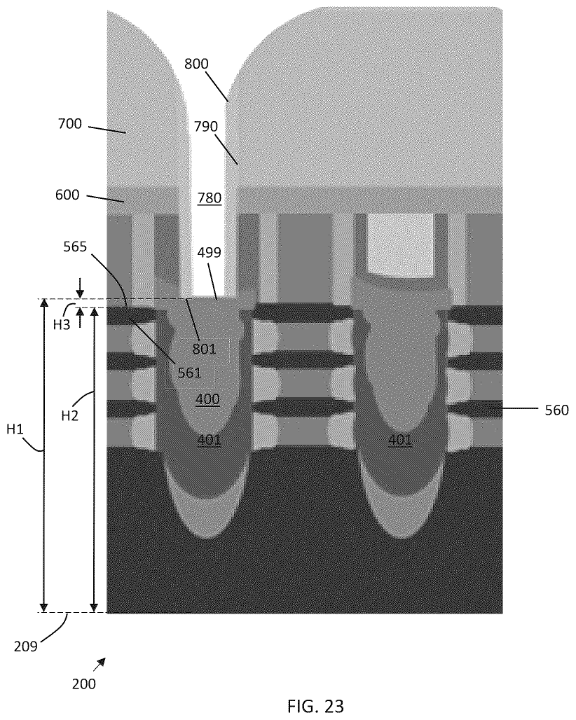

At FIG. 23, method 1000 includes, at operation S1182, etching the dielectric material 800 from over the top of the second ILD 700 and from over the surface 499 of the selected source/drain feature 400. For example, a directional etch may be performed such that the dielectric material 800 remains on the sidewalls 790 of the opening 780. After etching, the material 800 may be formed with an annular shape, lining the perimeter of the opening 780. FIG. 23 is an X-cut cross-sectional view.

In certain embodiments, the dielectric material 800 is a silicon nitride redistribution (SNR) layer or liner.

As shown in FIG. 23, the dielectric material 800 extends downward, in the vertical Z-direction to, and terminates at, a bottom edge 801. The bottom edge 801 is located at a first vertical distance or height H1, in the Z-direction, such as from a horizontal plane 209 defined by the device 200.

Further, the semiconductor nanosheets 560 include an uppermost nanosheet 561 having an uppermost surface 565 at a second vertical distance or height H2, in the Z-direction. Because the etch process for forming the opening 780 minimizes the recess amount of the source/drain feature 400, the first distance H1 is equal to or greater than the second distance H2. For example, the first distance H1 may be greater than the second distance H2 by a third vertical distance or height H3. In certain embodiments, the third distance H3 is from 0 to 12 nanometers, such as from 1 to 6 nanometers.

Collectively, the deposition process of operation S1181 and the etch process of operation S1182 represent an operation S1180 of forming a sidewall layer or side liner 800 in opening 780 over the selected source/drain feature 400 and on the opening sidewalls 790.

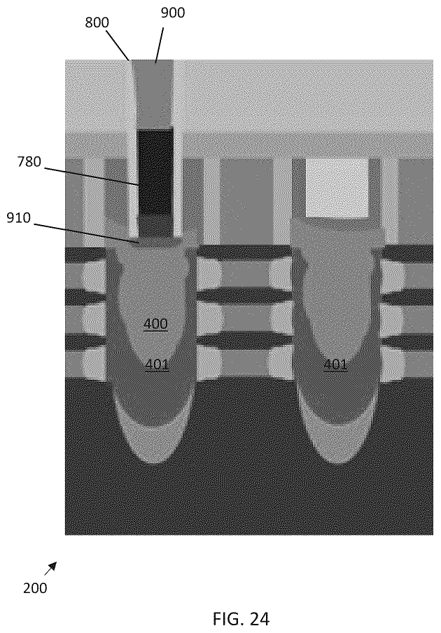

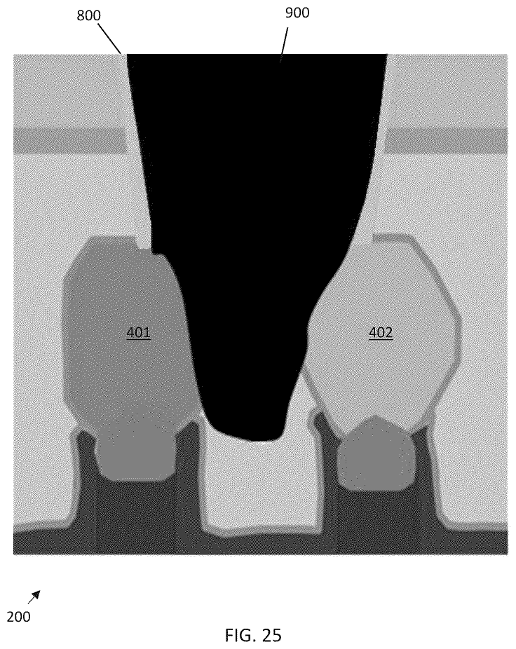

At FIG. 24, method 1000 includes, at operation S1190, forming a conductive interconnect 900 in the opening 780. FIG. 25 is a Y-cut cross-sectional view of the device 200 of FIG. 24.

As shown, operation S1190 may include siliciding an upper portion 910 of the source/drain feature 400, and depositing a conductive material(s) over the source/drain feature 400 to form the conductive interconnect 900 or source/drain contact 900. In certain embodiments, the conductive material(s) include metal(s), such as tungsten (W) or other suitable materials. FIG. 24 is an X-cut cross-sectional view.

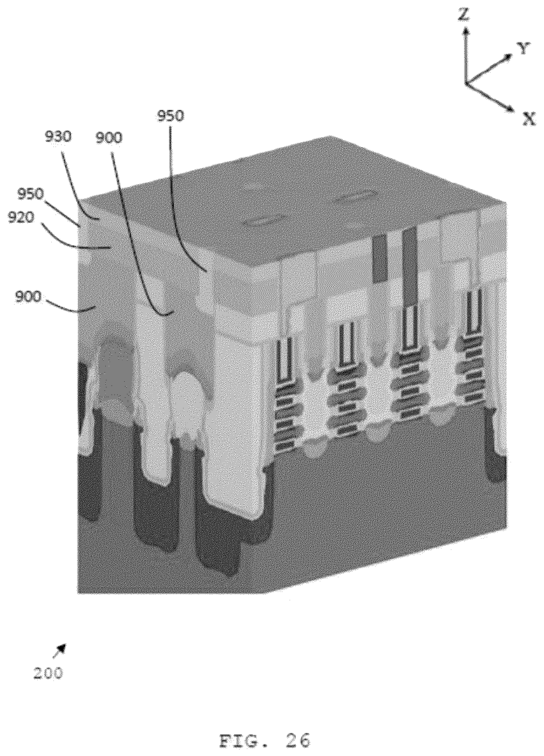

At FIG. 26, method 1000 includes, at operation S1200, further processing. FIG. 26 is a perspective view of the device 200. For example, the further processing may include formation of additional dielectric layers 920 and 930 over the device 200. Further, additional metal interconnect layers 950 may be formed. The further processing may include other back end of line (BEOL) processes.

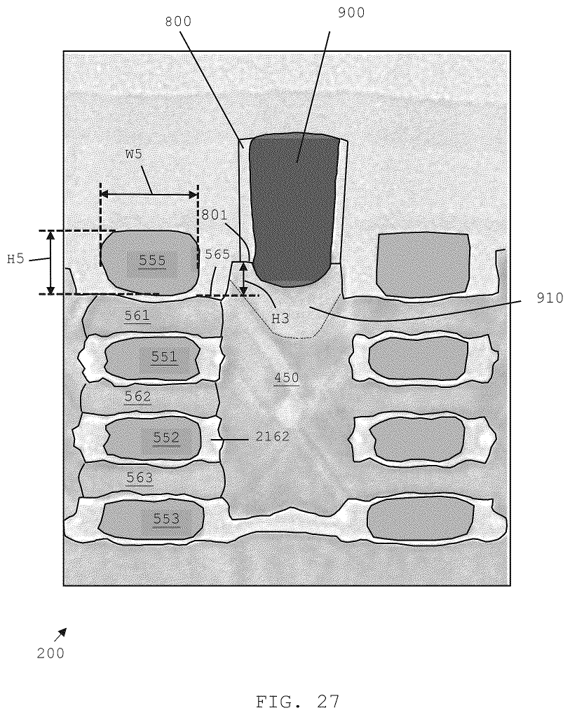

FIG. 27 is a transmission electron microscope (TEM) schematic image of a semiconductor device 200 formed according to method 1000. As shown, the device 200 includes three nanosheets, including a top or uppermost nanosheet 561, a bottom or lowest nanosheet 563, and an intermediate nanosheet 562.

In certain embodiments, the uppermost nanosheet 561, intermediate nanosheet 562, and lowest nanosheet 563 may independently have a vertical height of from 3 to 15 nanometers and a lateral width of from 9 to 100 nanometers.

Further, the device 200 a gate including an uppermost or top inner gate portion 551 directly below the nanosheet 561, an intermediate inner gate portion 552 directly below the nanosheet 562, and a lowest inner gate portion 553 direct below the nanosheet 563. Also, the gate includes an outer gate portion 555 directly above the nanosheet 562.

The outer gate portion 555 has a lateral width W5 in the Y-direction. In certain embodiments, width W5 is from 9 to 100 nanometers. The outer gate portion 555 has a vertical height H5 in the Z-direction. In certain embodiments, height H5 is from 5 to 30 nanometers. Each inner gate portion 551, 552, and 553 may independently have a vertical height of from 3 to 15 nanometers and a lateral width of from 9 to 100 nanometers.

The uppermost surface 565 is located a vertical distance H3 from the bottom edge 801 of the liner 800.

In certain embodiments, uppermost inner gate portion 551 is located at a depth of from 8 to 16 nanometers below the upper surface 565. In certain embodiments, intermediate inner gate portion 552 is located at a depth of from 20 to 30 nanometers below the upper surface 565. In certain embodiments, lowest inner gate portion 553 is located at a depth of from 32 to 50 nanometers below the upper surface 565.

In certain embodiments, a mid-height of the uppermost inner gate portion 551 is located at a depth of from 3 to 22 nanometers below the upper surface 565.

As shown in FIG. 26, upper portion 910 of the source/drain region 400 is converted to silicide. Upper portion 910 may include titanium, titanium silicide, and titanium nitride. In certain embodiments, the upper portion 910 may have a vertical height of from 5 to 120 angstrom (A).

As further shown in FIG. 26, each inner gate portion is surrounded by inner spacers 2162. In certain embodiments, the inner spacers 2162 are formed from SiO, SiN, SiOC, SiOCN, or other suitable materials. In certain embodiments, the inner spacers 2162 have a lateral width of from 1 to 12 nanometers.

In embodiments described herein, blockage of the conductive flow path between a metal interconnect 900 to the source/drain region 400 and the uppermost nanosheet channel 561 is prevented by performing a two-step etch process to open the source/drain feature 400. The second step of the etch is selective to etching the dielectric (450 and/or 440) at a faster rate than the silicon material of the source/drain feature 400. Therefore, the sidewall 790 of the opening 780 stops at the source/drain feature 400, rather than extending into the source/drain feature 400. The side liner (SNR layer) 800 is then formed in the opening 780 on the sidewalls 790 before the metal interconnect 900 is formed. The side liner 800 terminates at a bottom edge 801 that is located at or above the height of the uppermost nanosheet 561. As a result, the side liner 800 is not located in the direct flow path between the metal interconnect 900 and the uppermost nanosheet 561. For example, the side liner 800 is not located in a horizontal flow path between the metal interconnect 900 and the uppermost nanosheet 561.

In an embodiment, a method is provided and includes forming an epitaxial feature adjacent to a gate, wherein the gate lies over an uppermost surface of a semiconductor fin at a first vertical height; forming a first dielectric material over the epitaxial feature; forming a capping layer over the first dielectric material; forming a second dielectric material over the capping layer; forming an opening over the epitaxial feature, wherein the opening has a sidewall; and forming a side layer over the sidewall of the opening, wherein the side layer extends to a lowest edge at a second vertical height at or above the first vertical height.

In certain embodiments of the method, forming the opening over the epitaxial feature includes performing a first etch process selective to removing the capping layer relative to the first dielectric material, wherein the first etch process lands on the first dielectric material; and performing a second etch process selective to removing the first dielectric material relative to the epitaxial feature.

In certain embodiments of the method, the first etch process is performed at a first temperature with a first power; the second etch process is performed at a second temperature with a second power; the first temperature is lower than the second temperature; and the first power is greater than the second power.

In certain embodiments, the method further includes forming a liner over the epitaxial feature and forming the opening over the epitaxial feature includes uncovering the liner.

In certain embodiments of the method, the capping layer and the liner are the same material.

In certain embodiments, the method further includes converting an upper portion of the epitaxial feature to metal silicide; and forming a metal contact in the opening.

In certain embodiments of the method, forming the opening over the epitaxial feature includes performing a first etch process selective to removing the capping layer, wherein the first etch process lands on the first dielectric material; and performing a second etch process landing on the epitaxial feature.

In certain embodiments of the method, the second vertical height is from 0 to 12 nanometers higher than the first vertical height.

In certain embodiments of the method, forming the side layer over the sidewall of the opening includes depositing the side layer over a top surface of the second dielectric material, over the sidewall, and over a top surface of the epitaxial feature; and performing a directional etch to remove the side layer from the top surface of the second dielectric material and from the top surface of the epitaxial feature.

In certain embodiments of the method, the side layer is a silicon nitride redistribution (SNR) layer.

In another embodiment, a method is provided and includes forming a structure over a semiconductor substrate; forming a first dielectric material over the structure; forming a capping layer over the first dielectric material; forming a second dielectric material over the capping layer; performing a first etch process selective to removing the capping layer as compared to the first dielectric material, wherein the first etch process lands on the first dielectric material; and performing a second etch process selective to removing the first dielectric material as compared to the structure wherein the second etch process lands on the structure.

In certain embodiments, the method further includes forming a liner over the structure.

In certain embodiments of the method, the liner and the capping layer are the same material.

In certain embodiments of the method, the semiconductor substrate defines a horizontal plane; the structure is adjacent to a fin structure with an uppermost semiconductor surface at a first vertical distance over the horizontal plane; the first etch process and the second etch process form a cavity over the structure, and the cavity has sidewalls formed by the first dielectric material, the capping layer, and the second dielectric material; the method further includes forming a silicon nitride redistribution layer over the sidewalls of the cavity; the silicon nitride redistribution layer extends to a lowest edge at a minimum vertical distance from the horizontal plane; and the minimum vertical distance is greater than the first vertical distance.

In certain embodiments, the method further includes converting an upper portion of the structure to metal silicide; and forming a metal contact in the cavity.

In another embodiment, a semiconductor device includes a multi-gate structure over a semiconductor substrate including a top inner gate portion; a source/drain feature located laterally adjacent to the multi-gate structure; an interlayer dielectric layer over the multi-gate structure and the source/drain feature; a source/drain contact extending through the interlayer dielectric layer to the source/drain feature; and a side liner on the source/drain contact extending to a lowest edge in contact with the source/drain feature, wherein the lowest edge is located above the top inner gate portion.

In certain embodiments of the semiconductor device, the top inner gate portion has an uppermost surface; and the lowest edge is located above the uppermost surface of the top inner gate portion.

In certain embodiments of the semiconductor device, the multi-gate structure has an outer gate portion above the top inner gate portion, wherein the outer gate portion has an uppermost surface distanced from the uppermost surface of the top inner gate portion; and the lowest edge of the side liner is located below the uppermost surface of the multi-gate structure.

In certain embodiments of the semiconductor device, the side liner is a silicon nitride redistribution (SNR) layer.

In certain embodiments of the semiconductor device, the multi-gate structure has an outer gate portion above the top inner gate portion; a top nanosheet separates the outer gate portion from the top inner gate portion; the outer gate portion has a vertical thickness of from 5 to 30 nanometers; the top nanosheet has a vertical thickness of from 3 to 15 nanometers; and the top inner gate portion has a vertical thickness of from 3 to 15 nanometers.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present.

What is claimed is:

1. A method comprising:
forming an epitaxial feature adjacent to a gate, wherein the gate lies over an uppermost surface of a semiconductor fin at a first vertical height;
forming a first dielectric material over the epitaxial feature;
forming a capping layer over the first dielectric material;
forming a second dielectric material over the capping layer;
forming an opening over the epitaxial feature, wherein the opening has a sidewall; and
forming a side layer over the sidewall of the opening, wherein the side layer extends to a lowest edge at a second vertical height at or above the first vertical height.

2. The method of claim 1, wherein forming the opening over the epitaxial feature comprises
performing a first etch process selective to removing the capping layer relative to the first dielectric material, wherein the first etch process lands on the first dielectric material; and
performing a second etch process selective to removing the first dielectric material relative to the epitaxial feature.

3. The method of claim 2, wherein:
the first etch process is performed at a first temperature with a first power;
the second etch process is performed at a second temperature with a second power;
the first temperature is lower than the second temperature; and
the first power is greater than the second power.

4. The method of claim 1, further comprising forming a liner over the epitaxial feature, wherein forming the opening over the epitaxial feature comprises uncovering the liner.

5. The method of claim 4, wherein the capping layer and the liner are the same material.

6. The method of claim 1, further comprising:
converting an upper portion of the epitaxial feature to metal silicide; and
forming a metal contact in the opening.

7. The method of claim 1, wherein forming the opening over the epitaxial feature comprises
performing a first etch process selective to removing the capping layer, wherein the first etch process lands on the first dielectric material; and
performing a second etch process landing on the epitaxial feature.

8. The method of claim 1, wherein the second vertical height is from 0 to 12 nanometers higher than the first vertical height.

9. The method of claim 1, wherein forming the side layer over the sidewall of the opening comprises:
depositing the side layer over a top surface of the second dielectric material, over the sidewall, and over a top surface of the epitaxial feature; and
performing a directional etch to remove the side layer from the top surface of the second dielectric material and from the top surface of the epitaxial feature.

10. The method of claim 1, wherein the side layer is a silicon nitride redistribution (SNR) layer.

11. A method comprising:
forming a structure over a semiconductor substrate;
forming a first dielectric material over the structure;
forming a capping layer over the first dielectric material;
forming a second dielectric material over the capping layer;
performing a first etch process selective to removing the capping layer as compared to the first dielectric material, wherein the first etch process lands on the first dielectric material; and
performing a second etch process selective to removing the first dielectric material as compared to the structure wherein the second etch process lands on the structure.

12. The method of claim 11, further comprising forming a liner over the structure.

13. The method of claim 12, wherein the liner and the capping layer are the same material.

14. The method of claim 13, wherein:
the semiconductor substrate defines a horizontal plane;
the structure is adjacent to a fin structure with an uppermost semiconductor surface at a first vertical distance over the horizontal plane;
the first etch process and the second etch process form a cavity over the structure, wherein the cavity has sidewalls formed by the first dielectric material, the capping layer, and the second dielectric material;
the method further comprises forming a silicon nitride redistribution layer over the sidewalls of the cavity;
the silicon nitride redistribution layer extends to a lowest edge at a minimum vertical distance from the horizontal plane; and
the minimum vertical distance is greater than the first vertical distance.

15. The method of claim 14, further comprising:
converting an upper portion of the structure to metal silicide; and
forming a metal contact in the cavity.

16. A semiconductor device comprising:
a multi-gate structure over a semiconductor substrate including a top inner gate portion;
a source/drain feature located laterally adjacent to the multi-gate structure;
an interlayer dielectric layer over the multi-gate structure and the source/drain feature;
a source/drain contact extending through the interlayer dielectric layer to the source/drain feature; and
a side liner on the source/drain contact extending to a lowest edge in contact with the source/drain feature, wherein the lowest edge is located above the top inner gate portion.

17. The semiconductor device of claim 16, wherein:
the top inner gate portion has an uppermost surface; and
the lowest edge is located above the uppermost surface of the top inner gate portion.

18. The semiconductor device of claim 16, wherein:
the multi-gate structure has an outer gate portion above the top inner gate portion, wherein the outer gate portion has an uppermost surface distanced from the uppermost surface of the top inner gate portion; and
the lowest edge of the side liner is located below the uppermost surface of the multi-gate structure.

19. The semiconductor device of claim 16, wherein the side liner is a silicon nitride redistribution (SNR) layer.

20. The semiconductor device of claim 16, wherein:
the multi-gate structure has an outer gate portion above the top inner gate portion;
a top nanosheet separates the outer gate portion from the top inner gate portion;
the outer gate portion has a vertical thickness of from 5 to 30 nanometers;
the top nanosheet has a vertical thickness of from 3 to 15 nanometers; and
the top inner gate portion has a vertical thickness of from 3 to 15 nanometers.
